(19) United States
(12) Patent Application Publication
(10) Pub. No.: US 2023/0369282 A1
(43) Pub. Date: Nov. 16, 2023

(54) SEMICONDUCTOR PACKAGE AND METHOD OF FABRICATING THE SAME

(71) Applicant: Samsung Electronics Co., Ltd., Suwon-si (KR)

(72) Inventors: Donguk Kim, Suwon-si (KR); Jitaek Oh, Suwon-si (KR)

(21) Appl. No.: 18/052,252

(22) Filed: Nov. 3, 2022

(30) Foreign Application Priority Data
May 13, 2022 (KR) 10-2022-0058967

(51) Int. Cl. H01L 23/00; H01L 25/065; H01L 23/31

(52) U.S. Cl. CPC H01L 24/49; H01L 24/48; H01L 25/0657; H01L 23/3128; H01L 24/85; H01L 2224/48227; H01L 2224/49052; H01L 2225/06562; H01L 2225/0651; H01L 2224/85986

(57) ABSTRACT

Disclosed are semiconductor packages and their fabrication methods. The semiconductor package comprises a substrate including substrate pads, a first semiconductor chip mounted on the substrate and including first chip pads arranged in a first direction of the first semiconductor chip, and a first wire group that connects the substrate pads to the first chip pads and includes a first power/ground wire, a first signal wire, a second signal wire, and a second power/ground wire that are arranged in a second direction that is orthogonal to the first direction. A first top end of the first signal wire is closer horizontally to the first chip pads than is a second top end of the second signal wire.

### CROSS-REFERENCE TO RELATED APPLICATION

This U.S. nonprovisional application claims priority under 35 U.S.C § 119 to Korean Patent Application No. 10-2022-0058967, filed on May 13, 2022 in the Korean Intellectual Property Office, the disclosure of which is hereby incorporated by reference in its entirety.

### FIELD

The present inventive concepts relate to a semiconductor package and a method of fabricating the same, and more particularly, to a semiconductor package including a stacked integrated circuit and a method of fabricating the same.

### BACKGROUND

A typical stack package has a structure in which a number of substrates are stacked. For example, the stack package may include semiconductor chips that are sequentially stacked on a printed circuit board (PCB). Connection pads may be formed on the semiconductor chips. Bonding wires may be used to connect the connection pads, such that the semiconductor chips may be electrically coupled to each other. The printed circuit board is provided thereon with a logic chip that controls the semiconductor chips.

Portable devices have been in increasingly demand in recent electronic product markets, and as a result, reduction in size and weight of electronic parts mounted on the portable devices has been continuously required. In order to accomplish the reduction in size and weight of the electronic parts, there is need for technology to integrate a number of individual devices into a single package as well as technology to reduce individual sizes of mounting parts. In particular, semiconductor packages operated at high frequency signals are required to have compactness and excellent electrical characteristics.

### SUMMARY

Some embodiments of the present inventive concepts provide a semiconductor package with improved electrical properties and a method of fabricating the same.

According to some embodiments of the present inventive concepts, a semiconductor package may include: a substrate including substrate pads; a first semiconductor chip mounted on the substrate, the first semiconductor chip including first chip pads arranged in a first direction of the first semiconductor chip; and a first wire group that connects the substrate pads to the first chip pads, the first wire group including a first power/ground wire, a first signal wire, a second signal wire, and a second power/ground wire that are arranged in a second direction that is orthogonal to the first direction. A first top end of the first signal wire may be closer horizontally to the first chip pads than is a second top end of the second signal wire.

According to some embodiments of the present inventive concepts, a semiconductor package may include: a substrate; a plurality of semiconductor chips that are disposed in an offset stack structure along a first direction on the substrate; a plurality of bonding wires that connect one of the plurality of semiconductor chips to the substrate; and a molding layer that covers the plurality of semiconductor chips on the substrate. The plurality of bonding wires may include first wire groups and second wire groups that are alternately arranged in a second direction that is orthogonal to the first direction. Each of the first and second wire groups may include a signal wire and a power/ground wire. In each of the first wire groups, the signal wire may be disposed in the second direction of the power/ground wire. In each of the second wire groups, the signal wire may be disposed in a direction opposite to the second direction of the power/ground wire. In the first wire group and the second wire group that are adjacent to each other in the second direction, a first top end of the signal wire of the first wire group may be shifted in the first direction from a second top end of the signal wire of the second wire group.

According to some embodiments of the present inventive concepts, a method of fabricating a semiconductor package may include: providing a substrate including substrate pads; providing a semiconductor chip on the substrate and including chip pads, the chip pads including a first power/ground pad, a first input/output pad, a second input/output pad, and a second power/ground pad that are arranged along a first direction of the semiconductor chip; and performing bonding processes in which a bonding apparatus is used to bond bonding wires to the first power/ground pad, the first input/output pad, the second input/output pad, and the second power/ground pad. Each of the bonding processes may include: a first action in which the bonding apparatus descends to form a bonding portion on one of the chip pads; a second action in which the bonding apparatus departs from the one of the chip pads to form one of the bonding wires; a third action in which the one of the bonding wires is connected to one of the substrate pads; and a fourth action in which the bonding apparatus moves onto another of the chip pads. In the second action, a vertical departing distance of the bonding apparatus from the first power/ground pad and the first input/output pad may be greater than a departing distance of the bonding apparatus from the second input/output pad and the second power/ground pad.

### BRIEF DESCRIPTION OF THE DRAWINGS

FIG. 1 illustrates a perspective view showing a semiconductor package according to some embodiments of the present inventive concepts.

FIG. 2 illustrates a plan view showing a semiconductor package according to some embodiments of the present inventive concepts.

FIGS. 3 and 4 illustrate cross-sectional views showing a semiconductor package according to some embodiments of the present inventive concepts.

FIG. 5 illustrates a side view showing a semiconductor package according to some embodiments of the present inventive concepts.

FIG. 6 illustrates an enlarged view showing section A of FIG. 5.

FIG. 7 illustrates a perspective view showing a semiconductor package according to some embodiments of the present inventive concepts.

FIGS. 8 and 9 illustrate plan views showing a semiconductor package according to some embodiments of the present inventive concepts.

FIGS. 10 and 11 illustrate cross-sectional views showing a semiconductor package according to some embodiments of the present inventive concepts.

FIG. 12 illustrates a side view showing a semiconductor package according to some embodiments of the present inventive concepts.

FIG. 13 illustrates an enlarged view showing section B of FIG. 12.

FIG. 14 illustrates a perspective view showing a semiconductor package according to some embodiments of the present inventive concepts.

FIG. 15 illustrates a plan view showing a semiconductor package according to some embodiments of the present inventive concepts.

FIGS. 16 and 17 illustrate cross-sectional views showing a semiconductor package according to some embodiments of the present inventive concepts.

FIGS. 18, 19, 20, 21, 22, 23, 24, and 25 illustrate cross-sectional views showing a method of fabricating a semiconductor package according to some embodiments of the present inventive concepts.

### DETAILED DESCRIPTION

The following will now describe a semiconductor package and method of fabricating the same according to the present inventive concepts with reference to the accompanying drawings.

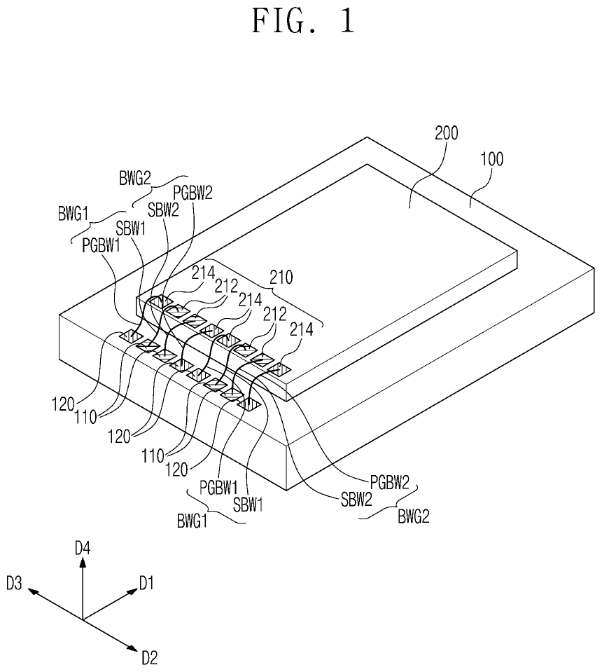

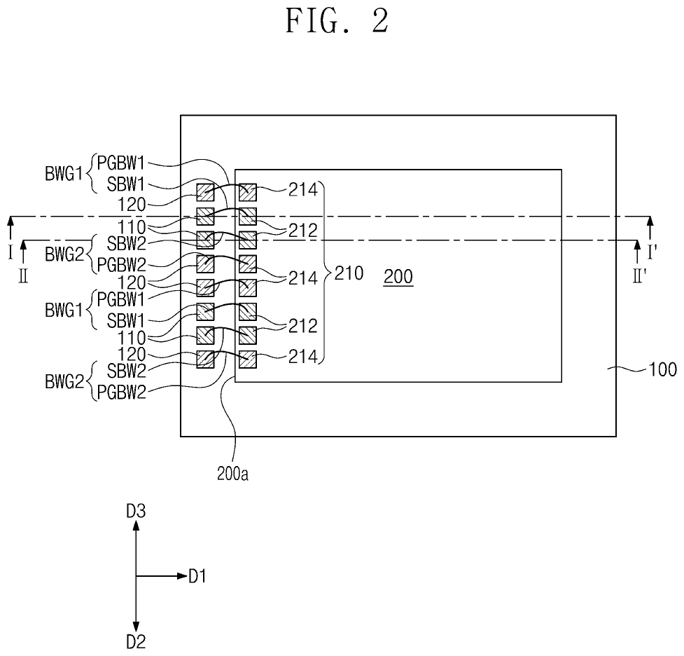

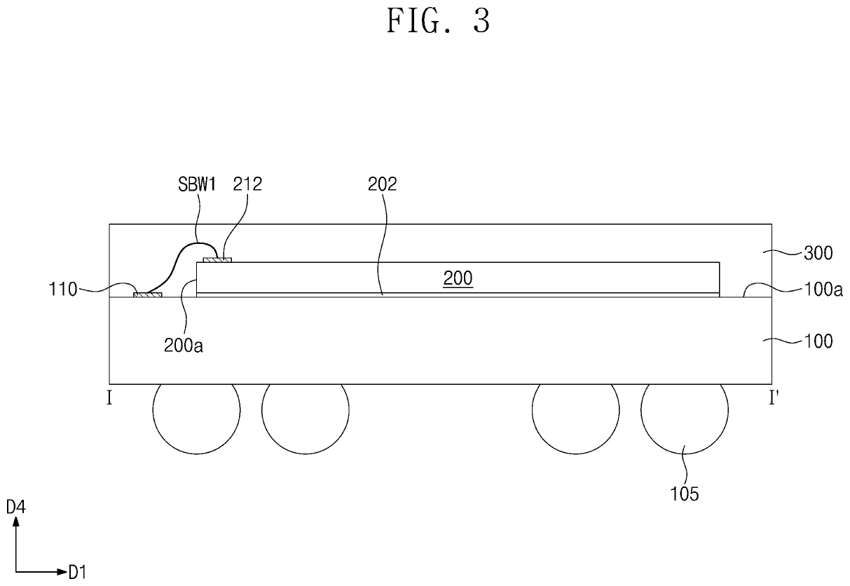

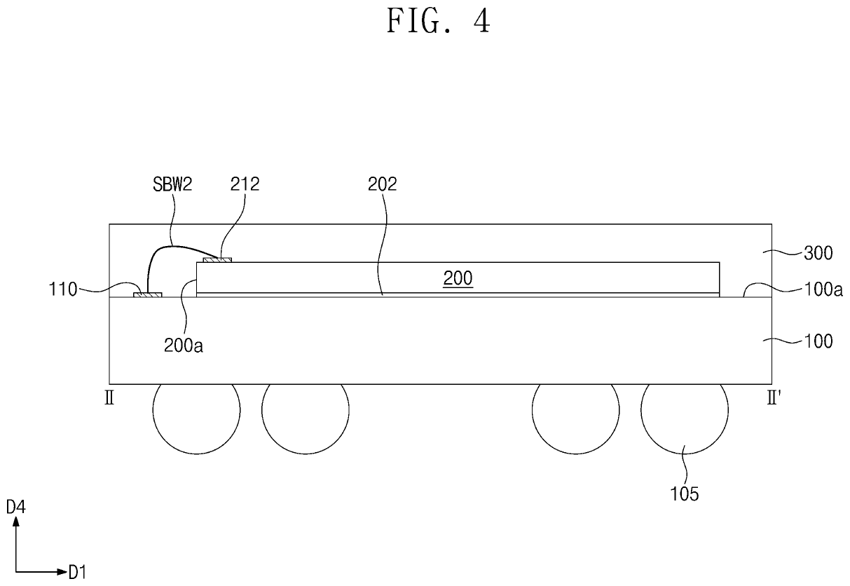

FIG. 1 illustrates a perspective view showing a semiconductor package according to some embodiments of the present inventive concepts. FIG. 2 illustrates a plan view showing a semiconductor package according to some embodiments of the present inventive concepts. FIGS. 3 and 4 illustrate cross-sectional views showing a semiconductor package according to some embodiments of the present inventive concepts. FIG. 3 corresponds to a cross section taken along line I-I′ of FIG. 2, and FIG. 4 corresponds to a cross section taken along line II-II′ of FIG. 2.

Referring to FIGS. 1 to 4, a package substrate 100 may be provided. The package substrate 100 may be a printed circuit board (PCB) having a signal pattern on a top surface thereof. The package substrate 100 may have a structure in which at least one dielectric layer and at least one wiring layer are alternately stacked.

An external terminal 105 may be provided on a bottom surface of the package substrate 100. The external terminal 105 may include a solder ball or a solder pad, and based on a type of the external terminal 105, a semiconductor package may be provided in the form of one of a ball grid array (BGA) type, a fine ball-grid array (FBGA) type, and a land grid array (LGA) type.

In this description, a first direction D1 is defined to indicate a direction parallel to a top surface 100a of the package substrate 100, a second direction D2 is defined to indicate a direction parallel to the top surface 100a of the package substrate 100 and orthogonal to the first direction D1, a third direction D3 is defined to indicate a direction opposite to the second direction D2, and a fourth direction D4 is defined to indicate a direction perpendicular to the top surface 100a of the package substrate 100.

The signal pattern of the package substrate 100 may include substrate pads 110 and 120. The substrate pads 110 and 120 may include first substrate pads 110 coupled to a signal input/output circuit of the package substrate 100, and may also include second substrate pads 120 coupled to a ground circuit of the package substrate 100. The first and second substrate pads 110 and 120 may be arranged in the second direction D2. A plurality of pairs of two neighboring first substrate pads 110 may be disposed in the second direction D2 alternately with a plurality of pairs of two neighboring second substrate pads 120. For example, as shown in FIGS. 1 and 2, one second substrate pad 120, two first substrate pads 110, two second substrate pads 120, two first substrate pads 110, and one second substrate pad 120 may be sequentially arranged along the second direction D2. The number and arrangement of the first and second substrate pads 110 and 120 are merely exemplary, and the present inventive concepts are not limited thereto.

A semiconductor chip 200 may be provided on the package substrate 100. The semiconductor chip 200 may be disposed in the first direction D1 of the first and second substrate pads 110 and 120. The semiconductor chip 200 may be spaced apart from the first and second substrate pads 110 and 120 in the first direction D1. The semiconductor chip 200 may be a memory chip or a logic chip.

The semiconductor chip 200 may have a top surface as an active surface. For example, chip pads 210 may be provided on the top surface of the semiconductor chip 200. The chip pads 210 may be arranged along a lateral surface 200a of the semiconductor chip 200 in a direction opposite to the first direction D1. For example, on the top surface of the semiconductor chip 200, the chip pads 210 may be disposed adjacent to the lateral surface 200a of the semiconductor chip 200 in a direction opposite to the first direction D1, and may be arranged along the second direction D2.

The chip pads 210 may include input/output pads 212 and power/ground pads 214. The input/output pads 212 and the power/ground pads 214 may be arranged in the second direction D2. A plurality of pairs of two neighboring input/output pads 212 may be disposed in the second direction D2 alternately with a plurality of pairs of two neighboring power/ground pads 214. For example, as shown in FIGS. 1 and 2, one power/ground pad 214, two input/output pads 212, two power/ground pads 214, two input/output pads 212, and one power/ground pad 214 may be sequentially arranged along the second direction D2. The number and arrangement of the input/output pads 212 and the power/ground pads 214 are merely exemplary, and the present inventive concepts are not limited thereto. The input/output pads 212 may be provided to transceive drive signals between the semiconductor chip 200 and the package substrate 100, and the power/ground pads 214 may be provided to transfer power or ground between the semiconductor chip 200 and the package substrate 100.

An adhesion layer 202 may be provided between the semiconductor chip 200 and the package substrate 100. The semiconductor chip 200 may be attached to the top surface 100a of the package substrate 100 through the adhesion layer 202 provided on a bottom surface of the semiconductor chip 200.

The semiconductor chip 200 may be electrically connected to the package substrate 100 through bonding wires SBW1, SBW2, PGBW1, and PGBW2. For example, the bonding wires SBW1, SBW2, PGBW1, and PGBW2 may connect the chip pads 210 of the semiconductor chip 200 to the substrate pads 110 and 120 of the package substrate 100.

The bonding wires SBW1, SBW2, PGBW1, and PGBW2 may include wire groups BWG1 and BWG2 that are arranged in the second direction D2. In this description, the wire group refers to a plurality of wires that are disposed adjacent to each other. The wire groups BWG1 and BWG2 may include first wire groups BWG1 and second wire groups BWG2 that are alternately arranged in the second direction D2.

Each of the first wire groups BWG1 may include a first signal wire SBW1 and a first power/ground wire PGBW1. The first signal wire SBW1 may be an input/output wire that transfers an input/output signal of the semiconductor chip 200, and the first power/ground wire PGBW1 may be a ground wire that transfers a ground signal to the semiconductor chip 200. For example, the first signal wire SBW1 may connect one of the input/output pads 212 of the semiconductor chip 200 to one of the first substrate pads 110 of the package substrate 100, and the first power/ground wire PGBW1 may connect one of the power/ground pads 214 of the semiconductor chip 200 to one of the second substrate pads 120 of the package substrate 100. The first signal wire SBW1 may be positioned in the second direction D2 of the first power/ground wire PGBW1.

Each of the second wire groups BWG2 may include a second signal wire SBW2 and a second power/ground wire PGBW2. The second signal wire SBW2 may be an input/output wire that transfers an input/output signal of the semiconductor chip 200, and the second power/ground wire PGBW2 may be a ground wire that transfers a ground signal to the semiconductor chip 200. For example, the second signal wire SBW2 may connect one of the input/output pads 212 of the semiconductor chip 200 to one of the first substrate pads 110 of the package substrate 100, and the second power/ground wire PGBW2 may connect one of the power/ground pads 214 of the semiconductor chip 200 to one of the second substrate pads 120 of the package substrate 100. The second signal wire SBW2 may be positioned in the third direction D3 of the second power/ground wire PGBW2.

Each of the wire groups BWG1 and BWG2 may have one signal wire SBW1 or SBW2 and one power/ground wire PGBW1 or PGBW2, and an arrangement direction of the first signal wires SBW1 and the first power/ground wires PGBW1 in the first wire groups BWG1 may be different from an arrangement direction of the second signal wires SBW2 and the second power/ground wires PGBW2 of the second wire groups BWG2. For example, as the first wire groups BWG1 and the second wire groups BWG2 are alternately disposed along the second direction D2, the signal wires SBW1 and SBW2 of neighboring first and second wire groups BWG1 and BWG2 may face each other or be adjacent each other. The power/ground wires PGBW1 and PGBW2 of neighboring first and second wire groups BWG1 and BWG2 may face each other or be adjacent each other. In this configuration, a plurality of pairs of neighboring first and second signal wires SBW1 and SBW2 may be disposed in the second direction D2 alternately with a plurality of pairs of neighboring first and second power/ground wires PGBW1 and PGBW2. For example, the first power/ground wire PGBW1, the first signal wire SBW1, the second signal wire SBW2, and the second power/ground wire PGBW2 may be sequentially arranged along the second direction D2, and this arrangement may be repeated.

The bonding wires SBW1 and PGBW1 of the first wire groups BWG1 may have different shapes from those of the bonding wires SBW2 and PGBW2 of the second wire groups BWG2.

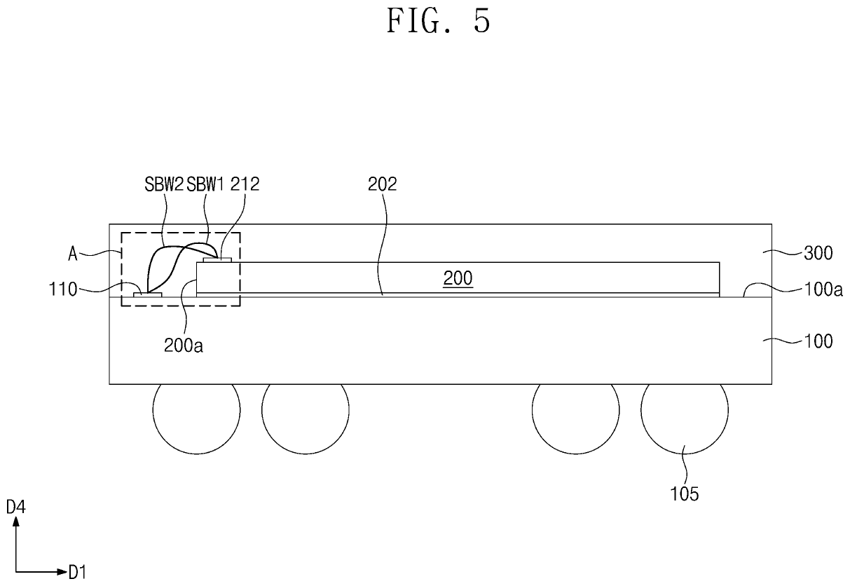

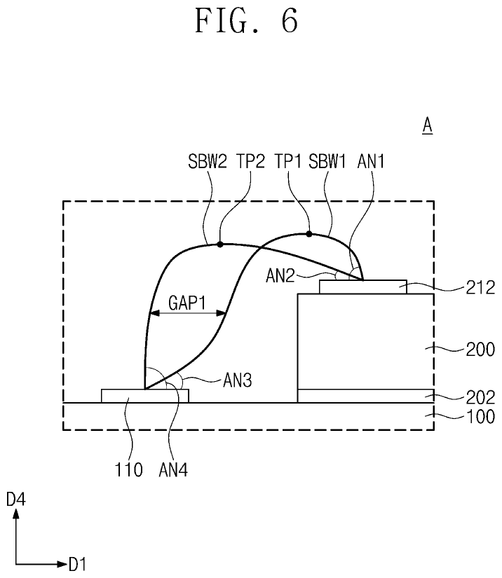

FIG. 5 illustrates a side view showing a semiconductor package according to some embodiments of the present inventive concepts. FIG. 5 depicts the semiconductor package viewed from a side in the second direction D2, and the first and second signal wires SBW1 and SBW2 are concurrently illustrated for convenience of description. FIG. 6 illustrates an enlarged view showing section A of FIG. 5.

Referring to FIGS. 1 to 6, the bonding wires SBW1, SBW2, PGBW1, and PGBW2 may extend from the chip pads 210 of the semiconductor chip 200 to the substrate pads 110 and 120 of the package substrate 100. For example, the bonding wires SBW1, SBW2, PGBW1, and PGBW2 may extend in the fourth direction D4 from top surfaces of the chip pads 210. Above the chip pads 210, the bonding wires SBW1, SBW2, PGBW1, and PGBW2 may be downwardly curved toward the substrate pads 110 and 120. The bonding wires SBW1, SBW2, PGBW1, and PGBW2 may extend toward the substrate pads 110 and 120 to come into connection with top surfaces of the substrate pads 110 and 120. When viewed laterally or from the side, top ends or top points of the bonding wires SBW1 and PGBW1 of the first wire groups BWG1 may be located at different positions from those of the bonding wires SBW2 and PGBW2 of the second wire groups BWG2. In this description, a top end or a top point of a bonding wire may indicate a bonding wire portion that is most far or highest in the fourth direction D4 from a top surface of the package substrate 100.

With reference to FIGS. 5 and 6, the following will comparatively describe neighboring first and second signal wires SBW1 and SBW2 of the first and second wire groups BWG1 and BWG2. A first top end TP1 of the first signal wire SBW1 may be shifted in the first direction D1 from a second top end TP2 of the second signal wire SBW2. For example, the first top end TP1 of the first signal wire SBW1 may be closer than the second top end TP2 of the second signal wire SBW2 to the semiconductor chip 200 or the input/output pads 212 of the semiconductor chip 200. The second top end TP2 of the second signal wire SBW2 may be closer than the first top end TP1 of the first signal wire SBW1 to the first substrate pads 110 of the package substrate 100. For example, the first signal wire SBW1 (or the top end TP1 thereof) may be formed closer to the input/output pads 212 than to the first substrate pads 110, and the second signal wire SBW2 (or the top end TP2 thereof) may be formed closer to the first substrate pads 110 than to the input/output pads 212.

A first angle AN1 made between the first signal wire SBW1 and the input/output pads 212 may be greater than a second angle AN2 made between the second signal wire SBW2 and the input/output pads 212. A third angle AN3 made between the first signal wire SBW1 and the first substrate pads 110 may be less than a fourth angle AN4 made between the second signal wire SBW2 and the first substrate pads 110.

The second signal wire SBW2 may have a length greater than that of the first signal wire SBW1.

When viewed laterally or from the side, the first signal wire SBW1 and the second signal wire SBW2 may be spaced apart from each other at a first gap GAP1. In this description, a first gap between bonding wires denotes a gap between portions that are most spaced apart from each other in the first direction D1 when viewed laterally. The first gap GAP1 may range from about 0.1 mm to about 2 mm. For example, the first gap GAP1 may range from about 1 mm to about 2 mm. However, no limitation is imposed on the first gap GAP1 between the first signal wire SBW1 and the second signal wire SBW2. The first gap GAP1 between the first signal wire SBW1 and the second signal wire SBW2 may be provided to have various values, if necessary.

When a semiconductor package operates, input/output signals transferred through the signal wires SBW1 and SBW2 may generate electromagnetic waves at the signal wires SBW1 and SBW2, and the electromagnetic waves may affect the input/output signals of adjacent other signal wires SBW1 and SBW2. According to some embodiments of the present inventive concepts, there may be provided neighboring first and second signal wires SBW1 and SBW2. As the first top end TP1 of the first signal wire SBW1 is shifted in the first direction D1 from the second top end TP2 of the second signal wire SBW2, a large distance may be provided between the first signal wire SBW1 and the second signal wire SBW2. Therefore, the first signal wire SBW1 and the second signal wire SBW2 may have therebetween minimum input/output signal interference caused by electromagnetic waves generated from the signal wires SBW1 and SBW2. As a result, there may be provided a semiconductor package with improved electrical properties.

When viewed laterally or from the side, top ends of the first power/ground wires PGBW1 of the first wire groups BWG1 may be located at different positions from those of top ends of the second power/ground wires PGBW2 of the second wire groups BWG2. An arrangement and shape of the first power/ground wire PGBW1 and the second power/ground wire PGBW2 may be substantially the same as or similar to those of the first signal wire SBW1 and the second signal wire SBW2 discussed with reference to FIGS. 5 and 6. For example, as regards neighboring first and second power/ground wires PGBW1 and PGBW2 of the first and second wire groups BWG1 and BWG2, a top end of the first power/ground wire PGBW1 may be shifted in the first direction D1 from a top end of the second power/ground wire PGBW2. For example, the first power/ground wire PGBW1 (or the top end thereof) may be formed closer to the input/output pads 212 or the power/ground pads 214 than to the first substrate pads 110 or the second substrate pads 120, and the second power/ground wire PGBW2 (or the top end thereof) may be formed closer to the first substrate pads 110 or the second substrate pads 120 than to the input/output pads 212 or the power/ground pads 214. An angle made between the first power/ground wire PGBW1 and the input/output pads 212 or the power/ground pads 214 may be greater than an angle made between the second power/ground wire PGBW2 and the input/output pads 212 or the power/ground pads 214. An angle made between the first power/ground wire PGBW1 and the first substrate pads 110 or the second substrate pads 120 may be less than an angle made between the second power/ground wire PGBW2 and the first substrate pads 110 or the second substrate pads 120. The second power/ground wire PGBW2 may have a length greater than that of the first power/ground wire PGBW1. When viewed laterally, the first power/ground wire PGBW1 may be spaced apart from the second power/ground wire PGBW2.

A molding layer 300 may be provided to cover the top surface 100a of the package substrate 100 and the semiconductor chip 200. The molding layer 300 may include a dielectric polymer material, such as an epoxy molding compound (EMC).

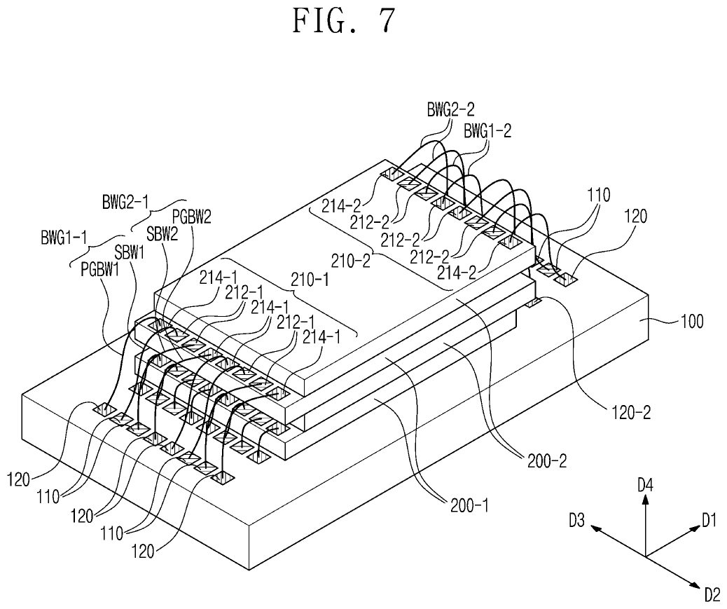

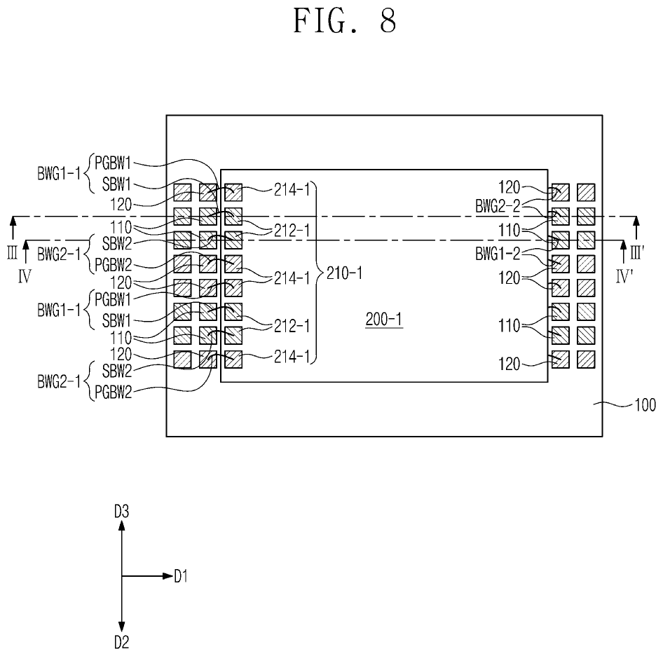

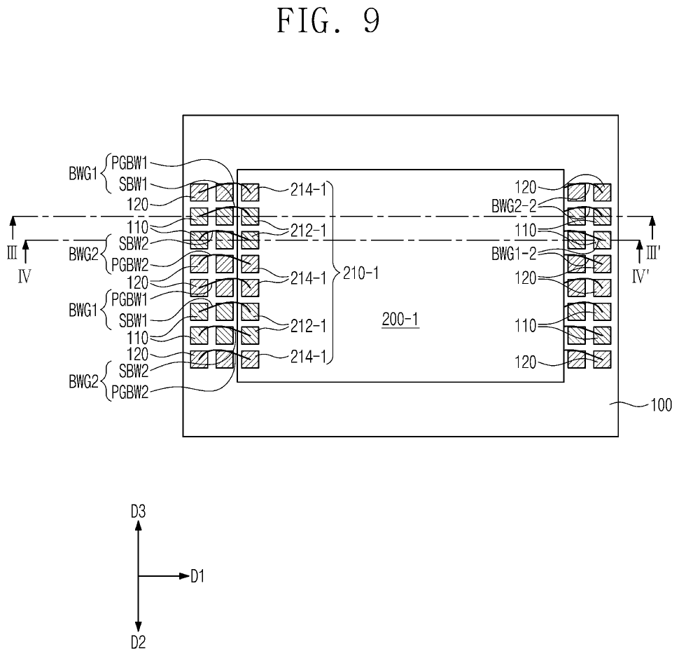

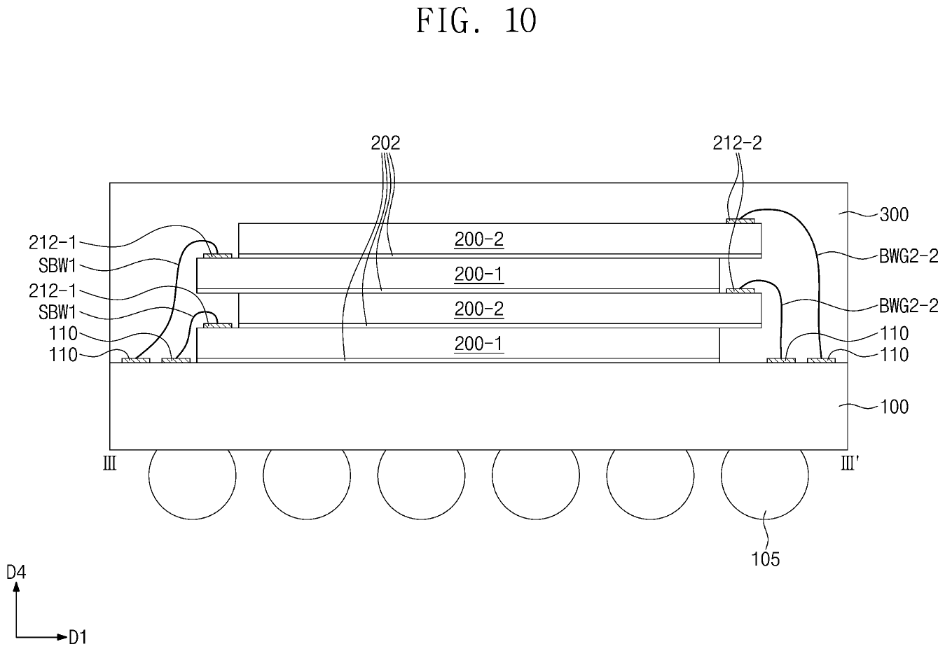

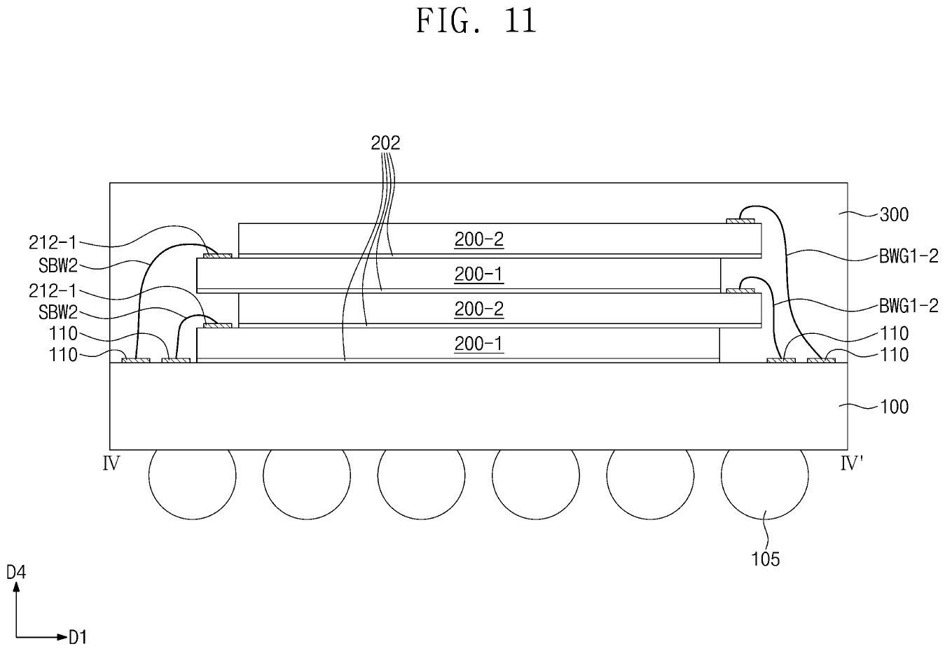

FIG. 7 illustrates a perspective view showing a semiconductor package according to some embodiments of the present inventive concepts. FIGS. 8 and 9 illustrate plan views showing a semiconductor package according to some embodiments of the present inventive concepts. FIGS. 10 and 11 illustrate cross-sectional views showing a semiconductor package according to some embodiments of the present inventive concepts. FIG. 10 corresponds to a cross section taken along line III-III′ of FIGS. 8 and 9, and FIG. 11 corresponds to a cross section taken along line IV-IV′ of FIGS. 8 and 9.

Referring to FIGS. 7 to 11, a semiconductor chip (see 200 of FIG. 1) may be provided in plural. FIGS. 7 to 13 depict an embodiment where four semiconductor chips 200-1 and 200-2 are provided, but the present inventive concepts are not limited thereto.

The semiconductor chips 200-1 and 200-2 may include first semiconductor chips 200-1 and second semiconductor chips 200-2. The first and second semiconductor chips 200-1 and 200-2 may be alternately stacked with each other. The first semiconductor chips 200-1 may be aligned or stacked in the fourth direction D4. For example, the first semiconductor chips 200-1 may have their lateral surfaces in a direction opposite to the first direction D1, and the lateral surfaces of the first semiconductor chips 200-1 may be positioned on the same plane. The second semiconductor chips 200-2 may be aligned in the fourth direction D4. For example, the second semiconductor chips 200-2 may have their lateral surfaces in the first direction D1, and the lateral surfaces of the second semiconductor chips 200-2 may be positioned on the same plane. The first semiconductor chips 200-1 may protrude in a direction opposite to the first direction D1 from their adjacent second semiconductor chips 200-2. The second semiconductor chips 200-2 may protrude in the first direction D1 from their adjacent first semiconductor chips 200-1. The first semiconductor chips 200-1 may protrude the same distance in a direction opposite to the first direction D1 from the second semiconductor chips 200-2 adjacent thereto, and the second semiconductor chips 200-2 may protrude the same distance in the first direction D1 from the first semiconductor chips 200-1 adjacent thereto. The first and second semiconductor chips 200-1 and 200-2 may be the same semiconductor chip. The present inventive concepts, however, are not limited thereto, and the first and second semiconductor chips 200-1 and 200-2 may be different kinds of semiconductor chips.

A configuration of each of the first semiconductor chips 200-1 may be substantially the same as or similar to that of the semiconductor chip 200 discussed with reference to FIGS. 1 to 6.

The first semiconductor chips 200-1 may be provided with first chip pads 210-1 on their top surfaces that do not overlap or align with the second semiconductor chips 200-2. For example, on the top surfaces of the first semiconductor chips 200-1, the first chip pads 210-1 may be disposed adjacent to lateral surfaces of the first semiconductor chips 200-1 in a direction opposite to the first direction D1. The first chip pads 210-1 may include first input/output pads 212-1 and first power/ground pads 214-1. The first input/output pads 212-1 and the first power/ground pads 214-1 may be arranged in the second direction D2. A plurality of pairs of two neighboring first input/output pads 212-1 may be disposed in the second direction D2 alternately with a plurality of pairs of two neighboring first power/ground pads 214-1.

An adhesion layer 202 may be provided on a bottom surface of the first semiconductor chip 200-1, and may attach the first semiconductor chip 200-1 to a top surface of the package substrate 100 or a top surface of the second semiconductor chip 200-2. An adhesion layer 202 may be provided between the uppermost first semiconductor chip 200-1 and the uppermost second semiconductor chip 200-2.

The first semiconductor chips 200-1 may be electrically connected to the package substrate 100 through first bonding wires SBW1, SBW2, PGBW1, and PGBW2. For example, the first bonding wires SBW1, SBW2, PGBW1, and PGBW2 may connect the first chip pads 210-1 of the first semiconductor chips 200-1 to the substrate pads 110 and 120 of the package substrate 100. The following will describe an arrangement of the first bonding wires SBW1, SBW2, PGBW1, and PGBW2 in connection between the first semiconductor chip 200-1 and the package substrate 100.

The first bonding wires SBW1, SBW2, PGBW1, and PGBW2 may include first wire groups BWG1-1 and second wire groups BWG2-1 that are alternately arranged in the second direction D2.

Each of the first wire groups BWG1-1 may include a first signal wire SBW1 and a first power/ground wire PGBW1. The first signal wire SBW1 may be positioned in the second direction D2 of the first power/ground wire PGBW1. Each of the second wire groups BWG2-1 may include a second signal wire SBW2 and a second power/ground wire PGBW2. The second signal wire SBW2 may be positioned in the third direction D3 of the second power/ground wire PGBW2.

Each of the first and second wire groups BWG1-1 and BWG2-1 may have one signal wire SBW1 or SBW2 and one power/ground wire PGBW1 or PGBW2, and an arrangement direction of the first signal wires SBW1 and the first power/ground wires PGBW1 in the first wire groups BWG1-1 may be different from an arrangement direction of the second signal wires SBW2 and the second power/ground wires PGBW2 of the second wire groups BWG2-1. For example, as the first wire groups BWG1-1 and the second wire groups BWG2-1 are alternately disposed along the second direction D2, the signal wires SBW1 and SBW2 of neighboring first and second wire groups BWG1-1 and BWG2-1 may face each other or be adjacent each other. In this configuration, a plurality of pairs of neighboring first and second signal wires SBW1 and SBW2 may be disposed in the second direction D2 alternately with a plurality of pairs of neighboring first and second power/ground wires PGBW1 and PGBW2.

The bonding wires SBW1 and PGBW1 of the first wire groups BWG1-1 may have different shapes from those of the bonding wires SBW2 and PGBW2 of the second wire groups BWG2-1.

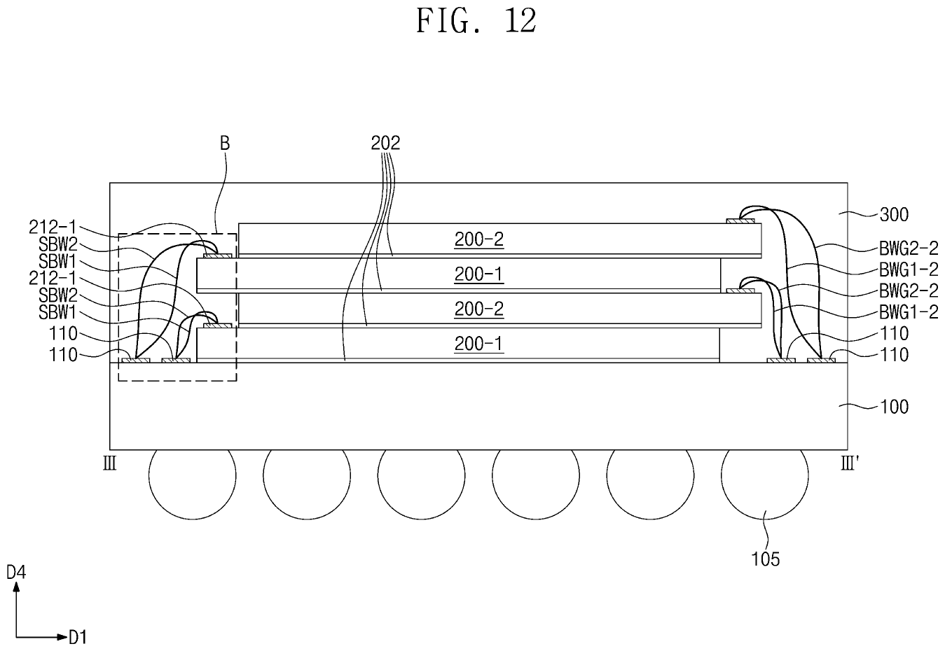

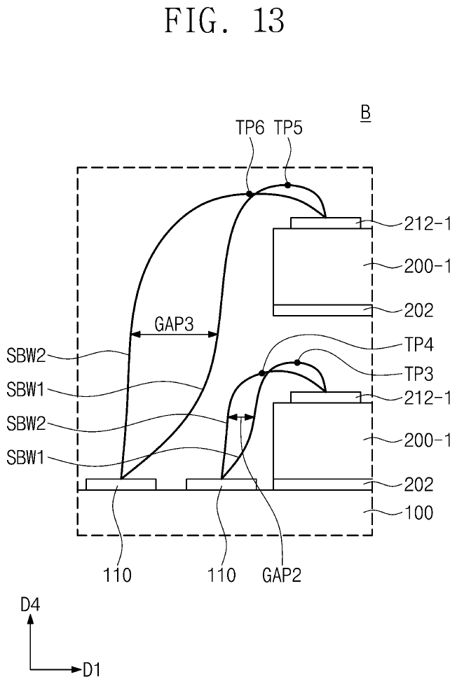

FIG. 12 illustrates a side view showing a semiconductor package according to some embodiments of the present inventive concepts. FIG. 12 depicts the semiconductor package viewed from a side in the second direction D2, and the first and second signal wires SBW1 and SBW2 are concurrently illustrated for convenience of description. FIG. 13 illustrates an enlarged view showing section B of FIG. 12.

Referring to FIGS. 7 to 13, the first bonding wires SBW1, SBW2, PGBW1, and PGBW2 may extend from the first chip pads 210-1 of the first semiconductor chip 200 to the substrate pads 110 and 120 of the package substrate 100. For example, the first bonding wires SBW1, SBW2, PGBW1, and PGBW2 may extend in the fourth direction D4 from top surfaces of the first chip pads 210-1. Above the first chip pads 210-1, the first bonding wires SBW1, SBW2, PGBW1, and PGBW2 may be downwardly curved toward the substrate pads 110 and 120. The first bonding wires SBW1, SBW2, PGBW1, and PGBW2 may extend toward the substrate pads 110 and 120 to come into connection with top surfaces of the substrate pads 110 and 120. When viewed laterally or from the side, top ends of the bonding wires SBW1 and PGBW1 of the first wire groups BWG1-1 may be located at different positions from those of the bonding wires SBW2 and PGBW2 of the second wire groups BWG2-1. In this description, a top end of a bonding wire may indicate a bonding wire portion that is most far or highest in the fourth direction D4 from a top surface of the package substrate 100.

The following will comparatively describe neighboring first and second signal wires SBW1 and SBW2 of the first and second wire groups BWG1-1 and BWG2-1. A first top end of the first signal wire SBW1 may be shifted in the first direction D1 from a top end of the second signal wire SBW2. For example, the first signal wire SBW1 (or the top end thereof) may be formed closer to the input/output pads 212-1 than to the first substrate pads 110, and the second signal wire SBW2 (or the top end thereof) may be formed closer to the first substrate pads 110 than to the input/output pads 212-1.

When viewed laterally or from the side, the first signal wire SBW1 and the second signal wire SBW2 may be spaced apart from each other. In this configuration, a gap between the first signal wire SBW1 and the second signal wire SBW2 may be changed in accordance with a position of the first semiconductor chip 200-1 from the package substrate 100. For example, as shown in FIG. 13, the signal wires SBW1 and SBW2 for connection of the bottommost first semiconductor chip 200-1 may be configured such that a top end TP3 of the first signal wire SBW1 may be closer in the first direction D1 to chip pads 212-1 than a top end TP4 of the second signal wire SBW2, and that the first signal wire SBW1 and the second signal wire SBW2 may be spaced apart from each other at a second gap GAP2. The signal wires SBW1 and SBW2 for connection of the first semiconductor chip 200-1 positioned above may be configured such that a top end TP5 of the first signal wire SBW1 may be closer in the first direction D1 to chip pads 212-1 than a top end TP6 of the second signal wire SBW2, and that the first signal wire SBW1 and the second signal wire SBW2 may be spaced apart from each other at a third gap GAP3. The third gap GAP3 may be larger than the second gap GAP2. When three or more first semiconductor chips 200-1 are stacked, an increase in distance of the first semiconductor chip 200-1 from the package substrate 100 may induce an increase in gap between the first signal wire SBW1 and the second signal wire SBW2.

An increase in distance of the first semiconductor chip 200-1 from the package substrate 100 may induce an increase in length of the signal wires SBW1 and SBW2 that connect the first semiconductor chip 200-1 to the package substrate 100. An increase in length of the signal wires SBW1 and SBW2 may induce an increase in amount of electromagnetic waves generated from the signal wires SBW1 and SBW2. According to some embodiments of the present inventive concepts, an increase in distance of the first semiconductor chip 200-1 from the package substrate 100 may induce an increase in gap between the first signal wire SBW1 and the second signal wire SBW2. Therefore, the first signal wire SBW1 and the second signal wire SBW2 may have therebetween minimum input/output signal interference caused by electromagnetic waves generated from the signal wires SBW1 and SBW2. As a result, there may be provided a semiconductor package with improved electrical properties.

Referring back to FIGS. 7 to 12, a configuration and arrangement of the second semiconductor chips 200-2 may be symmetric to that of the first semiconductor chips 200-1.

The second semiconductor chips 200-2 may be provided with second chip pads 210-2 on their top surfaces that do not overlap or align with the first semiconductor chips 200-1. For example, on the top surfaces of the second semiconductor chips 200-2, the second chip pads 210-2 may be disposed adjacent to lateral surfaces in the first direction D1 of the second semiconductor chips 200-2. The second chip pads 210-2 may include second input/output pads 212-2 and second power/ground pads 214-2. The second input/output pads 212-2 and the second power/ground pads 214-2 may be arranged in the second direction D2. A plurality of pairs of two neighboring second input/output pads 212-2 may be disposed in the second direction D2 alternately with a plurality of pairs of two neighboring second power/ground pads 214-2.

The second semiconductor chips 200-2 may be electrically connected through second bonding wires to the package substrate 100. For example, the second bonding wires may connect the second chip pads 210-2 of the second semiconductor chips 200-2 to the substrate pads 110 and 120 of the package substrate 100.

The second bonding wires may include wire groups BWG1-2 and BWG2-2 that are arranged in the second direction D2. The wire groups BWG1-2 and BWG2-2 may include first wire groups BWG1-2 and second wire groups BWG2-2 that are alternately arranged in the second direction D2.

Each of the first and second wire groups BWG1-2 and BWG2-2 may have one signal wire and one power/ground wire, and an arrangement direction of the signal wires and the first power/ground wires in the first wire groups BWG1-2 may be different from an arrangement direction of the signal wires and the power/ground wires of the second wire groups BWG2-2. The signal wires of neighboring first and second wire groups BWG1-2 and BWG2-2 may face each other or be adjacent to each other.

The bonding wires of the first wire groups BWG1-2 may have different shapes from those of the bonding wires of the second wire groups BWG2-2. Top ends of the bonding wires of the first wire groups BWG1-2 may be shifted in the first direction from top ends of the bonding wires of the second wire groups BWG2-2. For example, the bonding wires of the first wire groups BWG1-2 (or the top ends thereof) may be formed closer to the second input/output pads 212-2 than to the substrate pads 110 and 120, and the bonding wires of the second wire groups BWG2-2 (or the top ends thereof) may be formed closer to the substrate pads 110 and 120 than to the second input/output pads 212-2.

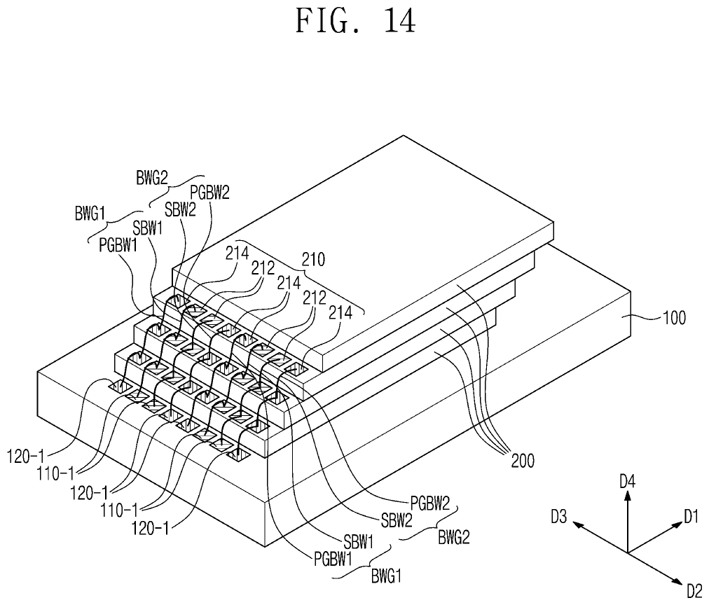

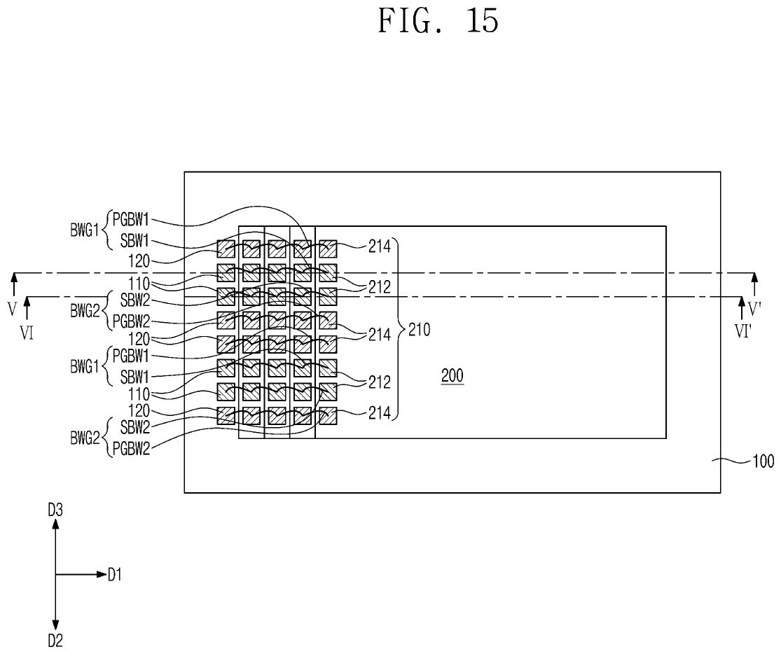

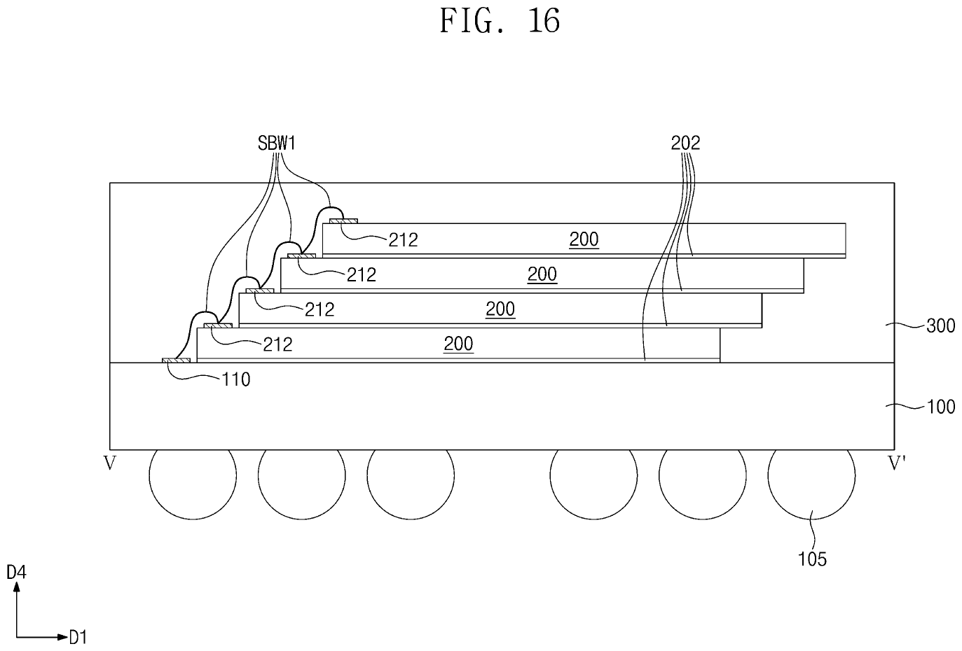

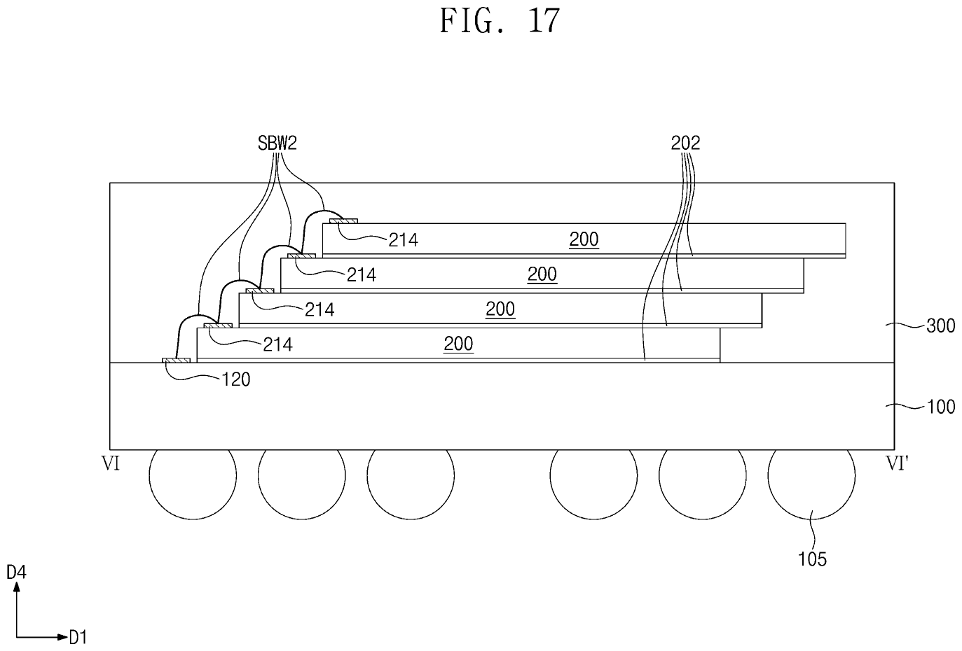

FIG. 14 illustrates a perspective view showing a semiconductor package according to some embodiments of the present inventive concepts. FIG. 15 illustrates a plan view showing a semiconductor package according to some embodiments of the present inventive concepts. FIGS. 16 and 17 illustrate cross-sectional views showing a semiconductor package according to some embodiments of the present inventive concepts. FIG. 16 corresponds to a cross section taken along line V-V′ of FIG. 15, and FIG. 17 corresponds to a cross section taken along line VI-VI′ of FIG. 15.

Referring to FIGS. 14 to 17, the semiconductor chip (see 200 of FIG. 1) may be provided in plural. FIGS. 14 to 17 depict an embodiment where four semiconductor chips 200 are provided, but the present inventive concepts are not limited thereto. The first semiconductor chips 200 may be substantially the same chip. The present inventive concepts, however, are not limited thereto, and the semiconductor chips 200 may be different kinds of semiconductor chips.

The semiconductor chips 200 may be disposed in an offset stack structure on the package substrate 100. For example, the semiconductor chips 200 may be stacked obliquely in the first direction D1 to constitute an ascending stepwise or stepped shape. An adhesion layer 202 may be provided between the semiconductor chips 200. The semiconductor chips 200 may be attached through the adhesion layers 202 provided on bottom surfaces thereof to top surfaces of other semiconductor chips 200 disposed thereunder, and a lowermost semiconductor chip 200 may be attached to a top surface of the package substrate 100 through the adhesion layer 202 provided on a bottom surface of the lowermost semiconductor chip 200. As the semiconductor chips 200 are stepwise stacked, the top surfaces of the semiconductor chips 200 may be partially exposed.

A configuration of each of the semiconductor chips 200 may be substantially the same as or similar to that of the semiconductor chip 200 discussed with reference to FIGS. 1 to 6.

The semiconductor chips 200 may be provided with chip pads 210 on regions of top surfaces thereof, which regions are not covered with other semiconductor chips 200. For example, on the top surfaces of the semiconductor chips 200, the chip pads 210 of the semiconductor chips 200 may be disposed adjacent to lateral surface in a direction opposite to the first direction D1. The chip pads 210 may include input/output pads 212 and power/ground pads 214. The input/output pads 212 and the power/ground pads 214 may be arranged in the second direction D2. A plurality of pairs of two neighboring input/output pads 212 may be disposed in the second direction D2 alternately with a plurality of pairs of two neighboring power/ground pads 214.

The semiconductor chips 200 may be electrically connected to the package substrate 100 through bonding wires SBW1, SBW2, PGBW1, and PGBW2. The bonding wires SBW1, SBW2, PGBW1, and PGBW2 may connect one semiconductor chip 200 to the package substrate 100 or may connect two adjacent semiconductor chips 200 to each other. For example, the bonding wires SBW1, SBW2, PGBW1, and PGBW2 may connect the chip pads 210 of a lowermost semiconductor chip 200 to the substrate pads 110 and 120 of the package substrate 100. For another example, the bonding wires SBW1, SBW2, PGBW1, and PGBW2 may connect the chip pads 210 of one semiconductor chip 200 to the chip pads 210 of another semiconductor chip 200.

The bonding wires SBW1, SBW2, PGBW1, and PGBW2 may include first wire groups BWG1 and second wire groups BWG2 that are alternately arranged in the second direction D2. Each of the first wire groups BWG1 may include a first signal wire SBW1 and a first power/ground wire PGBW1. The first signal wire SBW1 may be positioned in the second direction D2 of the first power/ground wire PGBW1. Each of the second wire groups BWG2 may include a second signal wire SBW2 and a second power/ground wire PGBW2. The second signal wire SBW2 may be positioned in the third direction D3 of the second power/ground wire PGBW2. An arrangement direction of the signal wires SBW1 and the power/ground wires PGBW1 of the first wire groups BWG1 may be different from an arrangement direction of the signal wires SBW2 and the power/ground wires PGBW2 of the second wire groups BWG2. For example, as the first wire groups BWG1 and the second wire groups BWG2 are alternately disposed along the second direction D2, the signal wires SBW1 and SBW2 of neighboring first and second wire groups BWG1 and BWG2 may face each other or be adjacent each other. In this configuration, a plurality of pairs of neighboring first and second signal wires SBW1 and SBW2 may be disposed in the second direction D2 alternately with a plurality of pairs of neighboring first and second power/ground wires PGBW1 and PGBW2.

The bonding wires SBW1 and PGBW1 of the first wire groups BWG1 may have different shapes from those of the bonding wires SBW2 and PGBW2 of the second wire groups BWG2. When viewed laterally or from the side, top ends of the bonding wires SBW1 and PGBW1 of the first wire groups BWG1 may be located at different positions from those of the bonding wires SBW2 and PGBW2 of the second wire groups BWG2. For example, the bonding wires SBW1 and PGBW1 of the first wire groups BWG1 (or the top ends thereof) may be formed closer to the input/output pads 212 than to the substrate pads 110 and 120, and the bonding wires SBW2 and PGBW2 of the second wire groups BWG2 (or the top ends thereof) may be formed closer to the substrate pads 110 and 120 than to the input/output pads 212.

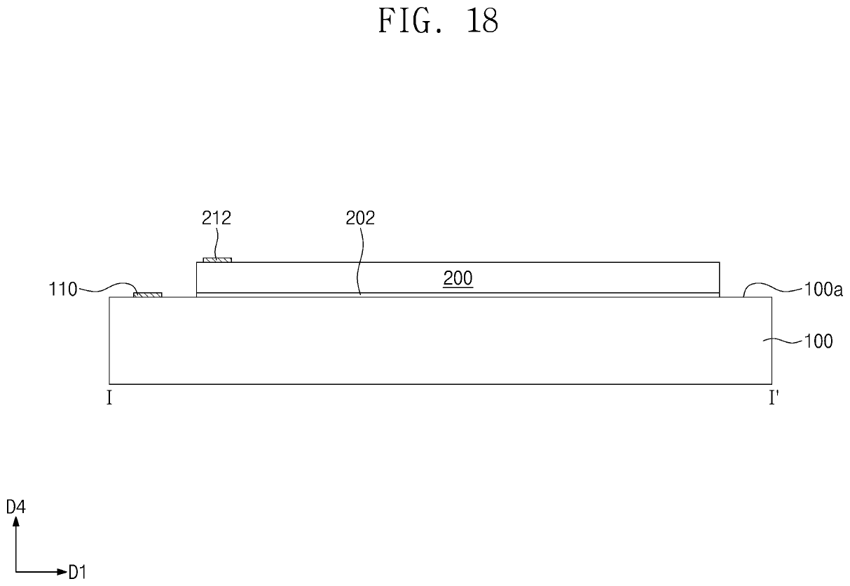

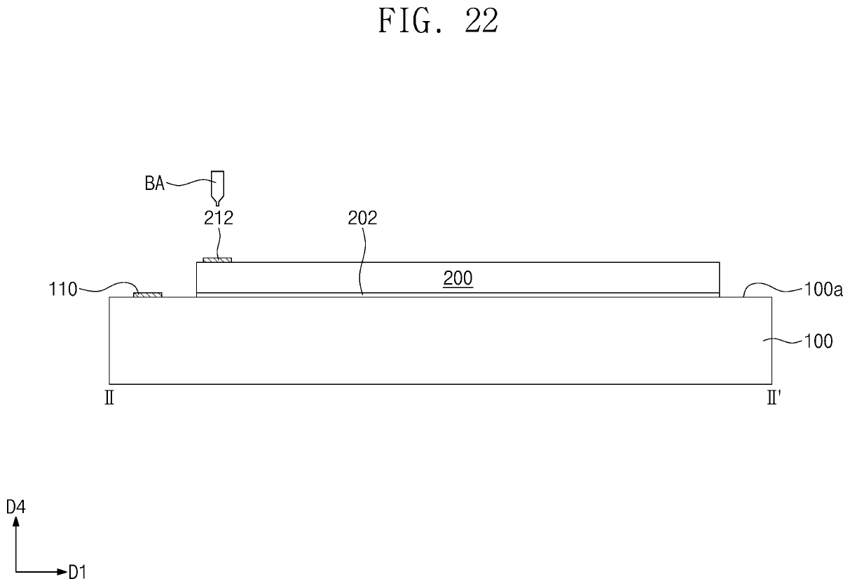

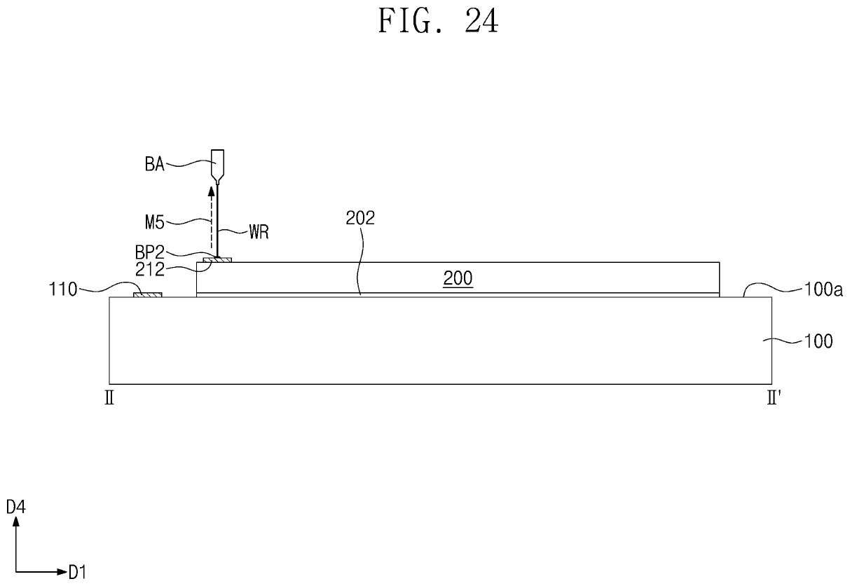

FIGS. 18 to 25 illustrate cross-sectional views showing a method of fabricating a semiconductor package according to some embodiments of the present inventive concepts. FIGS. 18 to 21 correspond to a cross section taken along line I-I′ of FIG. 2, and FIGS. 22 to 25 correspond to a cross section taken along line II-II′ of FIG. 2.

Referring to FIGS. 1, 2, and 18, a package substrate 100 may be provided. The package substrate 100 may include first and second substrate pads 110 and 120 provided on a top surface of the package substrate 100.

A semiconductor chip 200 may be attached to the package substrate 100. The semiconductor chip 200 may be face-up attached to the package substrate 100. The semiconductor chip 200 may have a top surface as an active surface. The semiconductor chip 200 may be attached through an adhesion layer 202 to the package substrate 100. For example, the adhesion layer 202 may be provided on a bottom surface of the semiconductor chip 200, and may attach the semiconductor chip 200 to the top surface of the package substrate 100.

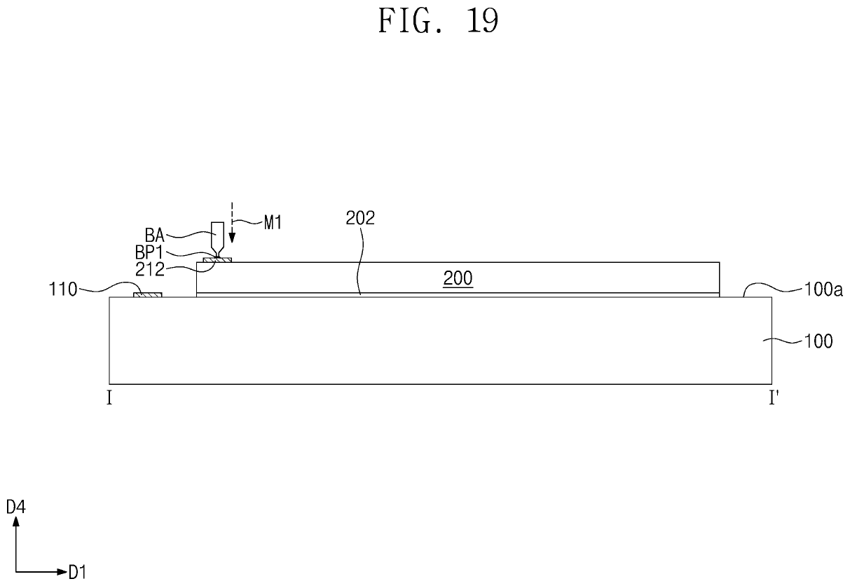

The semiconductor chip 200 may be wire-bonded to the package substrate 100. The semiconductor chip 200 may be connected to the package substrate 100 through bonding wires SBW1, SBW2, PGBW1, and PGBW2. With reference to FIGS. 19 to 25, the following will describe in detail a wire bonding process of the semiconductor chip 200.

Referring to FIGS. 1, 2, and 19, a first wire group BWG1 may be formed to connect the semiconductor chip 200 to the package substrate 100. For example, a first power/ground wire PGBW1 may be formed to connect one of power/ground pads 214 to one of the second substrate pads 120. The first power/ground wire PGBW1 may be formed by using a bonding apparatus BA. The formation of the first power/ground wire PGBW1 may be substantially the same as or similar to that of a first signal wire SBW1 which will be discussed below.

Afterwards, a first signal wire SBW1 may be formed. For example, the bonding apparatus BA may move onto one input/output pad 212. The bonding apparatus BA may descend along a first route M1 to contact a top surface of the input/output pad 212. The bonding apparatus BA may spray a solder material to form a first bonding portion BP1 on the top surface of the input/output pad 212.

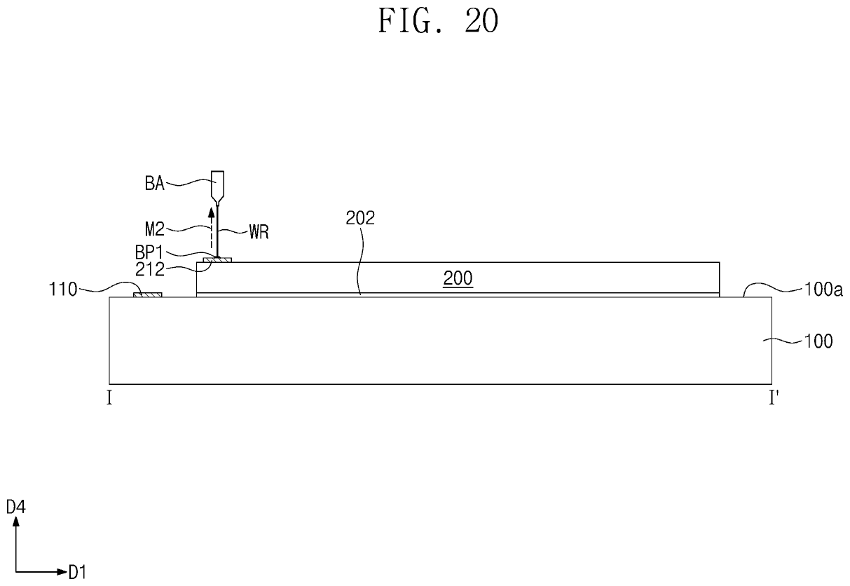

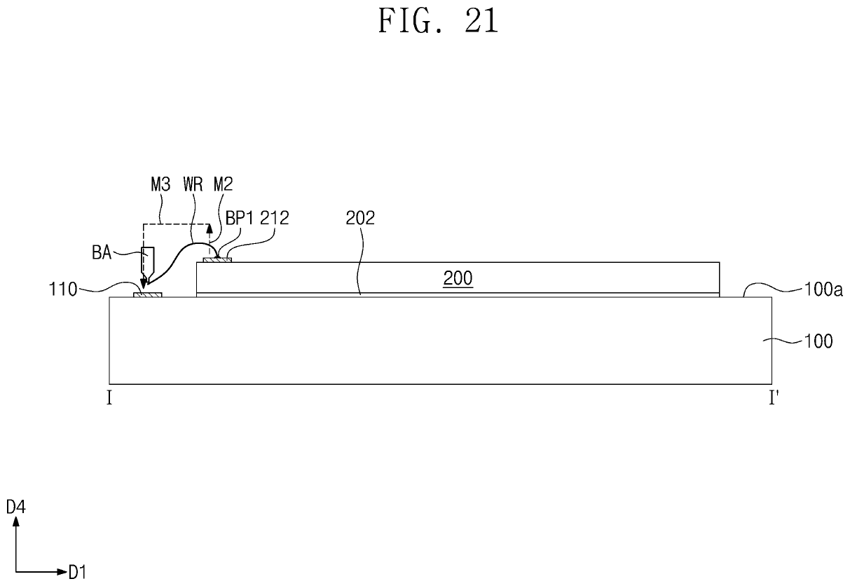

With reference to FIGS. 20 and 21, the following will still discuss the formation of the first signal wire SBW1.

Referring to FIGS. 1, 2, and 20, the bonding apparatus BA may move onto the input/output pad 212 while spraying the solder material. The bonding apparatus BA may move along a second route M2 which runs along the fourth direction D4.

Referring to FIGS. 1, 2, and 21, after the bonding apparatus BA moves onto one first substrate pad 110 while spraying the solder material, the bonding apparatus BA may move toward the first substrate pad 110 to thereby contact a top surface of the first substrate pad 110. In this step, after the bonding apparatus BA moves in a direction opposite to the first direction D1, the bonding apparatus BA may move along a third route M3 which runs in a direction opposite to the fourth direction D4.

The solder material sprayed from the bonding apparatus BA that moves along the second route (see M2 of FIG. 21) and the third route M3 may form a first signal wire SBW1 that connects the input/output pad 212 to the first substrate pad 110.

Referring to FIGS. 1, 2, and 22, a second wire group BWG2 may be formed to connect the semiconductor chip 200 to the package substrate 100. For example, a second power/ground wire PGBW2 may be formed to connect one of the input/output pads 212 to one of the first substrate pads 110. The input/output pad 212 and the first substrate pad 110 that are connected through the second signal wire SBW2 may be disposed in the second direction D2 from the input/output pad 212 and the first substrate pad 110 that are connected through the first signal wire SBW1. The second signal wire SBW2 may be formed by using the bonding apparatus BA. For example, the bonding apparatus BA that has performed the formation of the first signal wire SBW1 may move onto the input/output pad 212.

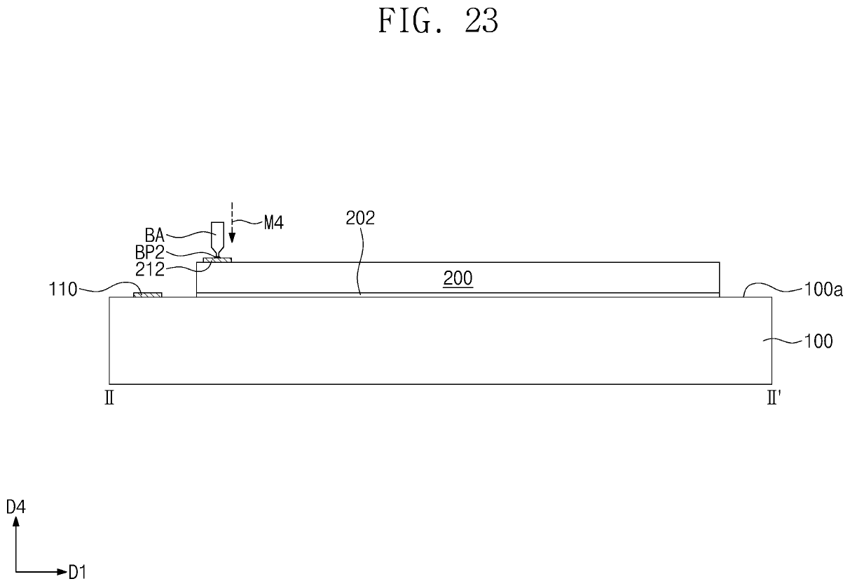

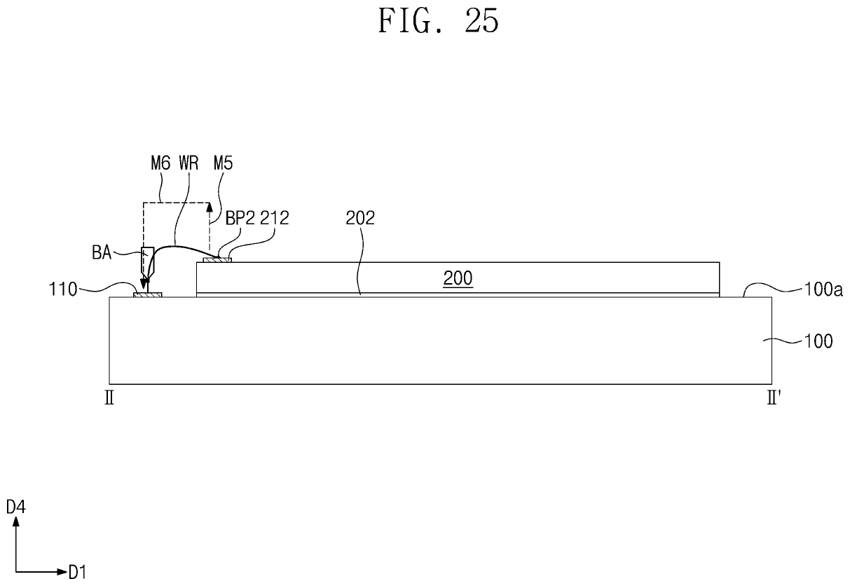

With reference to FIGS. 23 and 25, the following will still discuss the formation of the second signal wire SBW2.

Referring to FIGS. 1, 2, and 23, the bonding apparatus BA may move onto one input/output pad 212. The bonding apparatus BA may descend along a fourth route M4 to contact a top surface of the input/output pad 212. The bonding apparatus BA may spray a solder material to form a second bonding portion BP2 on the top surface of the input/output pad 212.

Referring to FIGS. 1, 2, and 24, the bonding apparatus BA may move onto the input/output pad 212 while spraying the solder material. The bonding apparatus BA may move along a fifth route M5 which runs along the fourth direction D4. A moving distance of the bonding apparatus BA along the fifth route M5 may be greater than that of the bonding apparatus BA along the second route M2. In this case, when the bonding apparatus BA moves onto the input/output pad 212, the bonding apparatus BA may spray a large amount of bonding material.

Referring to FIGS. 1, 2, and 25, after the bonding apparatus BA moves onto one first substrate pad 110 while spraying the solder material, the bonding apparatus BA may move toward the first substrate pad 110 to thereby contact a top surface of the first substrate pad 110. In this step, after the bonding apparatus BA moves in a direction opposite to the first direction D1, the bonding apparatus BA may move along a sixth route M6 which runs in a direction opposite to the fourth direction D4. A moving distance of the bonding apparatus BA along the sixth route M6 may be greater than that of the bonding apparatus BA along the third route M3. In this case, when the bonding apparatus BA moves onto the first substrate pad 110, the bonding apparatus BA may spray a large amount of bonding material.

The solder material sprayed from the bonding apparatus BA that moves along the fifth route (see M5 of FIG. 25) and the sixth route M6 may form a second signal wire SBW2 that connects the input/output pad 212 to the first substrate pad 110.

The formation of the second power/ground wire PGBW2 may be substantially the same as or similar to that of the second signal wire SBW2. For example, after the bonding apparatus BA moves onto one power/ground pad 214, the bonding apparatus BA may move onto one second substrate pad 120 while spraying a bonding material.

According to some embodiments of the present inventive concepts, the fifth route M5 along which the bonding apparatus BA moves from the chip pads 212 and 214 during the formation of the second wire group BWG2 may be greater than the second route M2 along which the bonding apparatus BA from the chip pads 212 and 214 during the formation of the first wire group BWG1. Therefore, crooked portions (or top ends) of the bonding wires PGBW2 and SBW2 of the second wire group BWG2 may be formed farther away from the chip pads 212 and 214 than crooked portions (or top ends) of the bonding wires PGBW1 and SBW1 of the first wire group BWG1. For example, the bonding wires PGBW1 and SBW1 of the first wire group BWG1 (or the top ends thereof) may be formed closer to the input/output pads 212 than to the first substrate pads 110, and the bonding wires PGBW2 and SBW2 of the second wire group BWG2 (or the top ends thereof) may be formed closer to the first substrate pads 110 than to the input/output pads 212. In a semiconductor package formed as discussed above, a large distance may be provided between the first signal wire SBW1 and the second signal wire SBW2. Therefore, the first signal wire SBW1 and the second signal wire SBW2 may have therebetween minimum input/output signal interference caused by electromagnetic waves generated from the signal wires SBW1 and SBW2. As a result, there may be formed a semiconductor package with improved electrical properties.

In addition, without additional processes, an adjustment of moving routes of the bonding apparatus BA may be sufficient to form the first signal wire SBW1 and the second signal wire SBW2 that have a wide gap therebetween. For example, a semiconductor package with improved electrical properties may be manufactured through a simplified fabrication process.

Thereafter, bonding processes may be continuously performed to connect the chip pads 212 and 214 of the semiconductor chip 200 to the substrate pads 110 and 120 of the package substrate 100.

Referring back to FIGS. 3-5, a molding layer 300 may be formed on the package substrate 100. For example, the molding layer 300 may be formed on the package substrate 100 so as to coat a molding material that covers the semiconductor chip 200 and a top surface of the package substrate 100.

After that, an external terminal 105 may be attached to a bottom surface of the package substrate 100.

In a semiconductor package according to some embodiments of the present inventive concepts, neighboring first and second signal wires may have their top ends that are shifted from each other in a horizontal direction, and thus a large distance may be provided between the first signal wire and the second signal wire. Therefore, the first signal wire and the second signal wire may have therebetween minimum input/output signal interference caused by electromagnetic waves generated from the signal wires. As a result, there may be provided a semiconductor package with improved electrical properties.

In addition, an increase in distance of a semiconductor chip from a package substrate may induce an increase in gap between the first signal wire and the second signal wire. Therefore, the first signal wire and the second signal wire may have therebetween minimum input/output signal interference caused by electromagnetic waves generated from the signal wires. As a result, there may be provided a semiconductor package with improved electrical properties.

Moreover, in a method of fabricating a semiconductor package according to some embodiments of the present inventive concepts, without additional processes, an adjustment of moving routes of a bonding apparatus may be sufficient to form the first signal wire and the second signal wire that have a wide gap therebetween. For example, a semiconductor package with improved electrical properties may be manufactured through a simplified fabrication process.

Although the present inventive concepts have been described in connection with some embodiments of the present inventive concepts illustrated in the accompanying drawings, it will be understood by one of ordinary skill in the art that variations in form and detail may be made therein without departing from the essential features of the present inventive concepts. The above disclosed embodiments should thus be considered illustrative and not restrictive.

What is claimed is:

1. A semiconductor package, comprising:
a substrate including substrate pads;
a first semiconductor chip mounted on the substrate, the first semiconductor chip including first chip pads arranged in a first direction of the first semiconductor chip; and
a first wire group that connects the substrate pads to the first chip pads, the first wire group including a first power/ground wire, a first signal wire, a second signal wire, and a second power/ground wire that are arranged in a second direction that is orthogonal to the first direction, and
wherein a first top end of the first signal wire is closer horizontally to the first chip pads than is a second top end of the second signal wire.

2. The semiconductor package of claim 1, wherein the first top end of the second signal wire is closer horizontally to the substrate pads than is the first top end of the first signal wire.

3. The semiconductor package of claim 1, wherein a first angle between the first signal wire and a top surface of one of the first chip pads is greater than a second angle between the second signal wire and a top surface of another of the first chip pads.

4. The semiconductor package of claim 1, wherein a third angle between the first signal wire and a top surface of one of the substrate pads is less than a fourth angle between the second signal wire and a top surface of another of the substrate pads.

5. The semiconductor package of claim 1, wherein the first wire group comprises a plurality of first wire groups,
wherein the plurality of first wire groups are arranged in the second direction, and
wherein the first power/ground wire of one of the plurality of first wire groups faces and is adjacent the second power/ground wire of another one of the plurality of first wire groups adjacent the first wire group.

6. The semiconductor package of claim 1, wherein a top end of the first power/ground wire is closer horizontally to the first semiconductor chip than is a top end of the second power/ground wire.

7. The semiconductor package of claim 1, wherein, when viewed laterally, a gap between the first signal wire and the second signal wire is in a range of about 0.1 mm to about 2 mm.

8. The semiconductor package of claim 1, wherein a length of the first signal wire and a length of the first power/ground wire are less than a length of the second signal wire and a length of the second power/ground wire.

9. The semiconductor package of claim 1, further comprising:
a second semiconductor chip stacked on the first semiconductor chip, the second semiconductor chip including second chip pads; and
a second wire group that connects the substrate pads to the second chip pads, the second wire group including a third power/ground wire, a third signal wire, a fourth signal wire, and a fourth power/ground wire that are arranged in the second direction.

10. The semiconductor package of claim 9, wherein, when viewed laterally, a gap between the third signal wire and the fourth signal wire is greater than a gap between the first signal wire and the second signal wire.

11. The semiconductor package of claim 9, further comprising a molding layer that covers the first semiconductor chip and the second semiconductor chip.

12. A semiconductor package, comprising:
a substrate;
a plurality of semiconductor chips that are disposed in an offset stack structure along a first direction on the substrate;
a plurality of bonding wires that connect one of the plurality of semiconductor chips to the substrate; and
a molding layer that covers the plurality of semiconductor chips on the substrate,
wherein the plurality of bonding wires include first wire groups and second wire groups that are alternately arranged in a second direction that is orthogonal to the first direction,
where each of the first and second wire groups includes a signal wire and a power/ground wire,
wherein, in each of the first wire groups, the signal wire is disposed in the second direction of the power/ground wire,
wherein, in each of the second wire groups, the signal wire is disposed in a direction opposite to the second direction of the power/ground wire, and
wherein, in the first wire group and the second wire group that are adjacent to each other in the second direction, a first top end of the signal wire of the first wire group is shifted in the first direction from a second top end of the signal wire of the second wire group.

13. The semiconductor package of claim 12, wherein
the first wire groups and the second wire groups are coupled to substrate pads of the substrate, and
first top ends of the signal wires of the first wire groups are further away horizontally from the substrate pads than are second top ends of the signal wires of the second wire groups.

14. The semiconductor package of claim 13, wherein a first angle between the signal wires of the first wire groups and top surfaces of the substrate pads is greater than a second angle between the signal wires of the second wire groups and the top surfaces of the substrate pads.

15. The semiconductor package of claim 12, wherein
the first wire groups and the second wire groups are coupled to chip pads of the semiconductor chips, and
first top ends of the signal wires of the first wire groups are closer horizontally to the chip pads than are second top ends of the signal wires of the second wire groups.

16. The semiconductor package of claim 15, wherein a third angle between top surfaces of the chip pads and the signal wires of the first wire groups is greater than a fourth angle between the top surfaces of the chip pads and the signal wires of the second wire groups.

17. The semiconductor package of claim 12, wherein, when viewed laterally, an increase in distance of the semiconductor chip from the substrate corresponds to an increase in gap between the signal wire of the first wire groups and the signal wire of the second wire groups.

18. A method of fabricating a semiconductor package, the method comprising:
providing a substrate including substrate pads;
providing a semiconductor chip on the substrate and including chip pads, the chip pads including a first power/ground pad, a first input/output pad, a second input/output pad, and a second power/ground pad that are arranged along a first direction of the semiconductor chip; and
performing bonding processes in which a bonding apparatus is used to bond bonding wires to the first power/ground pad, the first input/output pad, the second input/output pad, and the second power/ground pad,
wherein each of the bonding processes includes:
a first action in which the bonding apparatus descends to form a bonding portion on one of the chip pads;
a second action in which the bonding apparatus departs from the one of the chip pads to form one of the bonding wires;
a third action in which the one of the bonding wires is connected to one of the substrate pads; and
a fourth action in which the bonding apparatus moves onto another of the chip pads, and
wherein, in the second action, a vertical departing distance of the bonding apparatus from the first power/ground pad and the first input/output pad is greater than a departing distance of the bonding apparatus from the second input/output pad and the second power/ground pad.

19. The method of claim 18, wherein a moving distance of the bonding apparatus when the bonding wires are formed on the first power/ground pad and the first input/output pad is greater than a moving distance of the bonding apparatus when the bonding wires are formed on the second input/output pad and the second power/ground pad.

20. The method of claim 18, wherein top points of the bonding wires connected to the first power/ground pad and the first input/output pad are closer to the chip pads than are top points of the bonding wires connected to the second power/ground pad and the second input/output pad.
